(19) United States
(12) Patent Application Publication
(10) Pub. No.: US 2006/0144566 A1
(43) Pub. Date: Jul. 6, 2006

(54) System and method for cooling an integrated circuit device by electromagnetically pumping a fluid

(76) Inventors: Kip B. Jensen, Fruitland, ID (US); Neil L. Tang, Chandler, AZ (US)

Correspondence Address: INTEL CORPORATION, P.O. BOX 5326, SANTA CLARA, CA, 95056-5326, US

(21) Appl. No.: 11/027,033

(22) Filed: Dec. 30, 2004

(51) Int. Cl. H05K 7/20

(52) U.S. Cl. 165/104.28; 165/104.33; 361/699

(57) ABSTRACT

A fluid cooling system and method of cooling an integrated circuit die are disclosed. The cooling system includes a number of electromagnetic elements disposed on a fluid path, as well as one or more flow elements disposed within the fluid path. A fluid is also disposed in the fluid path. Each electromagnetic element is capable of generating a magnetic field that can exert a force on a flow element, causing the flow element to move through the fluid path. The moving flow element may create a pressure head within the fluid contained in the fluid path, causing the fluid to move. The moving fluid can transfer heat from a first heat exchanger to a second heat exchanger. Other embodiments are described and claimed.

### FIELD OF THE INVENTION

The disclosed embodiments relate generally to integrated circuit devices and, more particularly, to a fluid cooling system and method of cooling an integrated circuit die by electromagnetically pumping a fluid.

### BACKGROUND OF THE INVENTION

Illustrated in FIG. 1 is an example of an integrated circuit (IC) device 100. The IC device 100 includes a die 110 that is disposed on a substrate 120, this substrate often referred to as the “package substrate.” The die 110 may comprise a processing device, such as a microprocessor, a network processor, etc. A plurality of bond pads (or other leads) on the die 110 may be electrically connected to a corresponding plurality of lands (or other leads) on the substrate 120 by an array of solder bumps 130 (or columns, or other interconnects). Circuitry on the package substrate 120 can route signal lines from the die leads to locations on the substrate 120 where electrical connections can be established with a next-level component (e.g., a motherboard, a computer system, a circuit board, another IC device, etc.). For example, the substrate circuitry may route signal lines to a pin-grid array 125—or, alternatively, a ball-grid array—formed on a lower surface of the package substrate 120. The pin-grid (or ball-grid) array then electrically couples the die to the next-level component, which includes a mating array of terminals (e.g., pin sockets, bond pads, etc.).

During operation of the IC device 100, heat generated by the die 110 can damage the die if this heat is not transferred away from the die or otherwise dissipated. To remove heat from the die 110, the die 110 may ultimately be coupled with a heat sink 170 via a number of thermally conductive components, including a first thermal interface 140, a heat spreader 150, and a second thermal interface 160. The first thermal interface 140 couples the heat spreader 150 with an upper surface of the die 110, and this thermal interface conducts heat from the die to the heat spreader. Heat spreader 150 conducts heat laterally within itself to “spread” the heat outwards from the die 110, and the heat spreader 150 also conducts heat to the second thermal interface 160. The second thermal interface 160 couples the heat spreader 150 with heat sink 170, and the second thermal interface conducts heat from the heat spreader to the heat sink, which transfers heat to the ambient environment. Heat sink 170 may include a plurality of fins 172, or other similar features providing increased surface area, to facilitate convection of heat to the surrounding air. The IC device 100 may also include a seal element 180 to seal the die 110 from the operating environment. Seal element 180 and heat spreader 150 may comprise a single component (e.g., a lid).

The heat sink 170, heat spreader 150, and first and second thermal interfaces 140, 160 collectively form a cooling system for the die 110. The power dissipation of microprocessors and other processing devices generally increases with each design generation, as the operating frequencies of these devices are ratcheted upwards. Also, the design and operating conditions for a die may lead to “hot spots” on the die where the local temperature is significantly greater than in surrounding regions on the die, and a failure to adequately extract heat from such hot spots may lead to damage and/or a degradation in performance of the die. Thus, the thermal performance of die cooling systems in future generations of IC devices will become increasingly critical.

### BRIEF DESCRIPTION OF THE DRAWINGS

FIG. 1 is a schematic diagram illustrating a cross-sectional elevation view of an exemplary integrated circuit device.

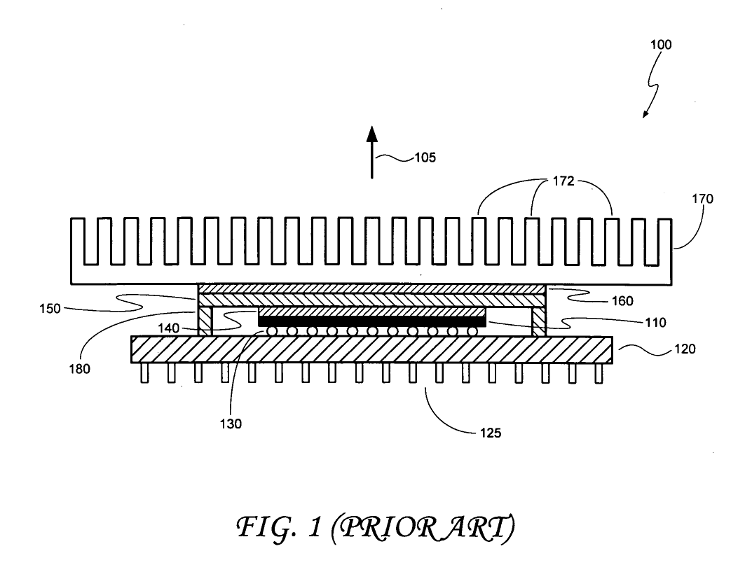

FIG. 2 is a schematic diagram illustrating an embodiment of a fluid cooling system that employs the electromagnetic pumping of a fluid.

FIGS. 3A-3C are schematic diagrams, each illustrating an embodiment of a magnetically conductive element.

FIG. 4 is a schematic diagram further illustrating operation of the fluid cooling system of FIG. 2.

FIG. 5 is a block diagram illustrating an embodiment of a method of cooling an integrated circuit device by electromagnetically pumping a fluid.

FIG. 6 is a schematic diagram illustrating an embodiment of an integrated circuit device incorporating an embodiment of a fluid cooling system that employs the electromagnetic pumping of a fluid.

FIGS. 7A-7B are schematic diagrams, each illustrating an embodiment of a cold plate shown in FIG. 6.

FIG. 8 is a schematic diagram illustrating an embodiment of a computer system, which may include a component having an embodiment of the fluid cooling system that employs the electromagnetic pumping of a fluid.

### DETAILED DESCRIPTION OF THE INVENTION

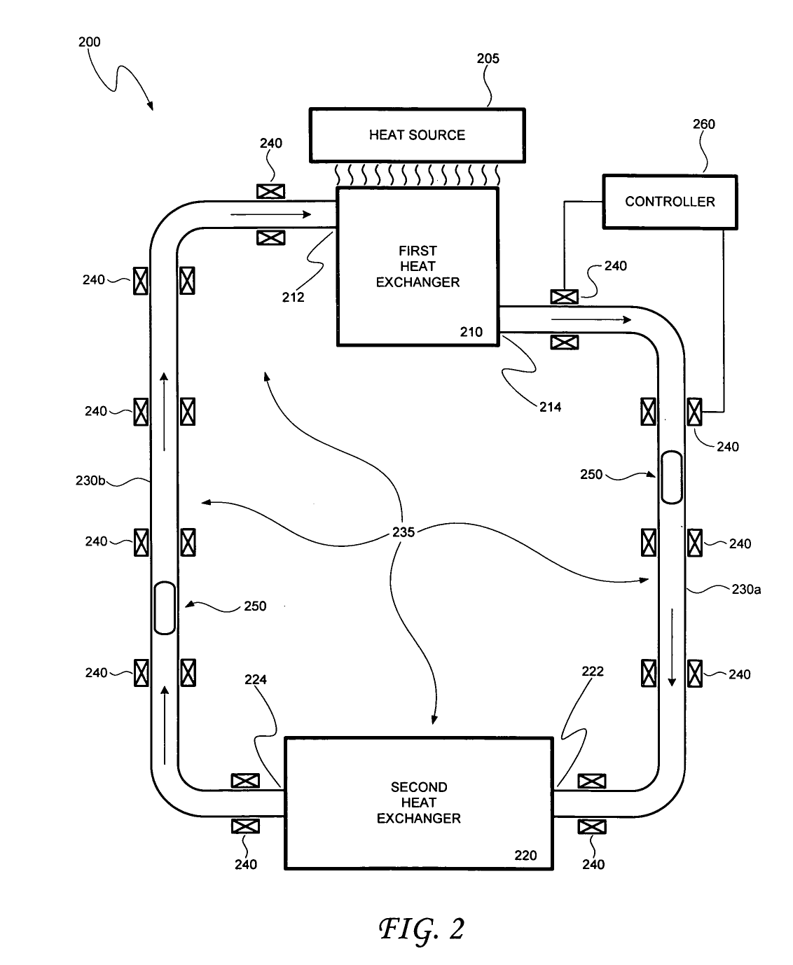

Illustrated in FIG. 2 is an embodiment of a fluid cooling system 200. The cooling system 200 includes a first heat exchanger 210, a second heat exchanger 220, a first fluid conduit 230a, a second fluid conduit 230b, a number of electromagnetic elements 240, one or more flow elements 250, and a controller 260. A heat source 205 is thermally coupled with the first heat exchanger 210. Heat source 205 may comprise any device that generates heat or any device that is to be cooled. According to one embodiment, the heat source 205 comprises an integrated circuit device. For example, in one embodiment, the heat source 205 comprises a processing device, such as a microprocessor, a network processor, an application specific integrated circuit (ASIC), or field programmable gate array (FPGA).

As noted above, the heat source 205 is thermally coupled with the first heat exchanger 210. The first heat exchanger 210 includes an inlet 212 and an outlet 214. Outlet 214 is coupled with the first fluid conduit 230a, and inlet 212 is coupled with the second fluid conduit 230b (both the first and second fluid conduits 230a, 230b being coupled with the second heat exchanger 220, as will be described below). First heat exchanger 210 may comprise any device which can receive heat from heat source 205 and transfer heat to a fluid moving through this heat exchanger.

In one embodiment, the first heat exchanger 210 comprises a plate constructed from metal (or other thermally conductive material) that is thermally coupled to the heat source 205. For example, the heat source (e.g., an integrated circuit die) may be attached (both mechanically and thermally) to the metal plate using a layer of solder or other thermal interface material. The metal plate includes one or more channels, and a fluid is caused to flow through this channel (or channels). Heat from the heat source 205 is conducted to the metal plate, and heat is also conducted through the metal plate to channel(s). Heat may then be transferred to the moving fluid, which heats the fluid, and this heated fluid flows out of the metal plate (and to the second heat exchanger 220). The above-described metal plate may be referred to as a “cold plate.”

The second heat exchanger 220 includes an inlet 222 and an outlet 224. The inlet 222 is coupled with the first fluid conduit 230a, which is also coupled with the outlet 214 of first heat exchanger 210, as noted above. Outlet 224 is coupled with the second fluid conduit 230b, the second fluid conduit being coupled with the inlet 212 of the first heat exchanger, as also noted above. The second heat exchanger 220 may comprise any device that can receive a heated fluid from the first heat exchanger 210 and cool this fluid. In one embodiment, the second heat exchanger 220 comprises a device that cools the heated fluid by dissipating heat to the surrounding environment (e.g., ambient air). For example, according to one embodiment, the second heat exchanger 220 comprises a multi-fin heat sink constructed from a metal (or other thermally conductive material). The heat sink includes one or more channels to receive the heated fluid, and heat from the fluid is transferred to the metal heat sink. Heat is then conducted through the heat sink to a number of fins (or other surface features providing increased surface area), and heat is transferred from these fins to the surrounding environment (e.g., as by convection).

Each of the first and second fluid conduits 230a, 230b may comprise any device through which a fluid may flow and, further, through which a flow element 250 can move, as will be described below. According to one embodiment, each of the first and second fluid conduits 230a, 230b comprises a section of tubing. The tubing may comprise a flexible material, such as a plastic material, or a more rigid material, such as a metal. This tubing may be coupled with the first and second heat exchangers 210, 220 using any suitable device or technique (e.g., as by a threaded connection, by swaging, by epoxy bonding, by brazing or welding, etc.).

The first and second fluid conduits 230a, 230b, as well as the first and second heat exchangers 210, 220 (e.g., the channel or channels formed therein), provide a flow path 235. In one embodiment, this flow path 235 comprises a closed-loop flow path. This flow path 235 provides for the circulation of a fluid between the first and second heat exchangers 210, 220, and the fluid may be circulated through the flow path by electromagnetically pumping the fluid, as will be described below. It should be understood that, although referred to as a closed-loop flow path in some embodiments, such a closed-loop flow path may suffer from a small amount of leakage. Also, in other embodiments, the flow path 235 may not be a closed-loop system.

The fluid circulating in flow path 235 may comprise any fluid capable of receiving heat from the first heat exchanger 210 and transporting heat to the second heat exchanger 220. In one embodiment, the fluid comprises a liquid. For example, the fluid may comprise water, a mixture of water and a corrosion inhibitor, a mixture of water and ethylene glycol, a mixture of water and propylene glycol, an alcohol (e.g., ethanol), or a light weight oil. Also, either single-phase cooling (e.g., where the fluid remains a liquid) or two-phase cooling (e.g., where a portion of a liquid coolant is vaporized to create a liquid-vapor mixture) may be employed.

As noted above, the system 200 includes a number of electromagnetic elements 240 and one or more flow elements 250, as well as the controller 260. The electromagnetic elements 240 can move the flow element or elements 250 through the flow path 235, and the moving flow elements can create a pressure head within the flow path, which may cause the fluid within the flow path to circulate. Thus, the electromagnetic elements 240 and flow elements 250, in conjunction with the controller 260, may form a system for pumping fluid through the flow path 235, including the first and second heat exchangers 210, 220.

As suggested above, each of the electromagnetic elements 240 may be in communication (e.g., electrical communication) with the controller 260, and the controller will control switching of the electromagnetic elements—e.g., between either an “ON” state and an “OFF” state—in a desired sequence, as will be described in more detail below. Although, for ease of illustration, only two of the electromagnetic elements 240 are illustrated in FIG. 2 as being in communication with the controller 260, it should be understood that all of the electromagnetic elements 240 may be in communication with the controller. The controller 260 may comprise any suitable circuitry or device capable of controlling operation of the electromagnetic elements 240. In one embodiment, the heat source 205 comprises and integrated circuit die, and the controller 260 comprises circuitry formed on this die. In another embodiment, the controller 260 comprises a device or circuitry external to the heat source 205.

Each of the electromagnetic elements 240 may comprise any device which is capable of generating a magnetic field sufficient to move a flow element 250 through the flow path 235. In one embodiment, an electromagnetic element 240 comprises a toroidal shaped electromagnet that extends around a portion of the flow path 235 (e.g., around either of the first and second fluid conduits 230a, 230b, or around a channel in either of the first and second heat exchangers 210, 220). According to one embodiment, a toroidal shaped electromagnet may comprise a coil of wire (e.g., copper wire). Such a toroidal shaped electromagnet can generate a magnetic field that may exert a “pulling” force (and, perhaps, a “pushing” force) on a flow element 250.

A flow element 250 may comprise any device which can be caused to move under application of a magnetic field (e.g., a magnetic field generated by one of the electromagnetic elements 240). As previously noted, movement of the flow element (or elements) 250 creates a pressure head within the fluid contained in the flow path 235, and this pressure head will pump the fluid through the flow path. Any suitable number of flow elements 250 may be disposed in the flow path 235. In one embodiment, one flow element 250 is used. In other embodiments, two or more flow elements 250 are employed. For example, as shown in FIG. 2, two flow elements 250 may be disposed in the flow path 235. According to one embodiment, where two or more flow elements 250 are used, these elements are maintained in an equidistantly (or approximately equidistant) spaced-apart relationship within the flow path 235. In other embodiments, however, the flow elements 250 may be spaced-apart in some other fashion.

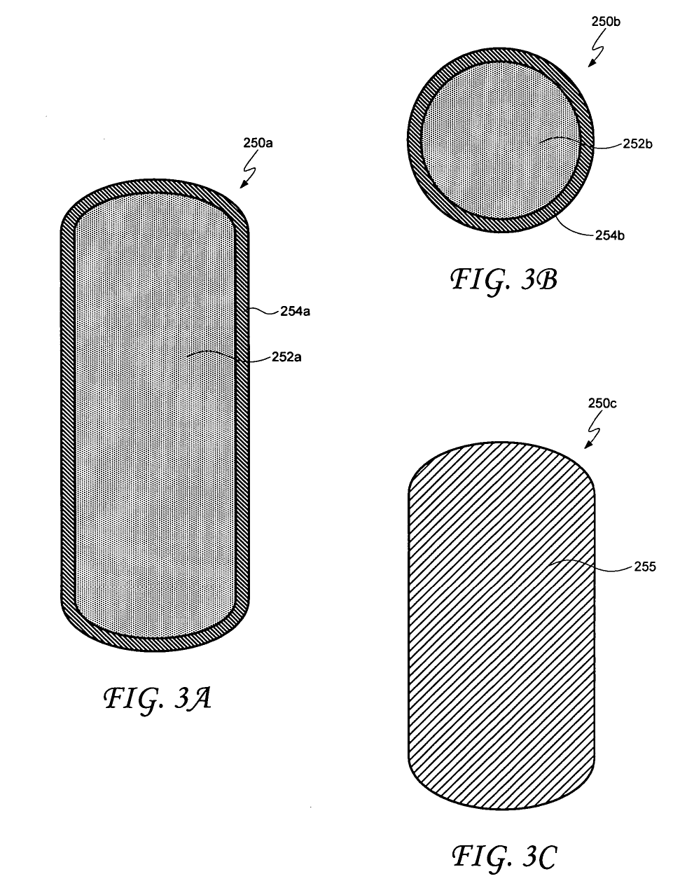

With reference to FIG. 3A, in one embodiment, a flow element 250a comprises a ferrous substance 252a (or other substance which can be propelled under application of a magnetic field) contained within a flexible shell 254a. According to one embodiment, the ferrous substance 252a comprises a plurality of metallic particles suspended in a viscous fluid, such as an oil. In a further embodiment, the ferrous substance 252a comprises a plurality of metallic particles. The outer flexible shell 254a may be constructed from a polymer material or other flexible material. The flexibility of the outer shell 254a may facilitate movement of the flow element 250a through the tubing and/or channels that comprise flow path 235 (e.g., by allowing the flow element to deform). However, in other embodiments, the outer shell 254a may comprise a more rigid material (e.g., a metal).

A flow element may be of any suitable shape or configuration. For example, as shown in FIG. 3A, a flow element 250a may be cylindrical in shape. However, in another embodiment, a flow element 250b may be spherical in shape, as illustrated by the embodiment of FIG. 3B. The flow element 250b shown in FIG. 3B comprises a ferrous substance 252b contained in a flexible spherical shell 254b, both which may be similar to the ferrous substance 252a and shell 254a, respectively, that were described above.

In a further embodiment, a flow element may comprise a solid piece of material. For example, referring to FIG. 3C, a flow element 250c comprises a cylindrical shaped body 255 formed of a ferrous metal (or other material which can be propelled under application of a magnetic field). Such a solid ferrous body may be of any other suitable shape (e.g., spherical).

In yet another embodiment, a flow element may itself be magnetic. For example, a flow element may comprise a permanent magnet of a suitable shape (e.g., a cylindrical shape, a spherical shape, etc.). As will be explained below, for a ferrous flow element 250, an electromagnetic element 240 can exert a “pulling” force on the flow element as that flow element enters the electromagnetic element's magnetic field. However, where a flow element 250 is itself magnetic, an electromagnetic element 240 may also exert a “pushing” force on the flow element as the flow element is moving out of this element's magnetic field.

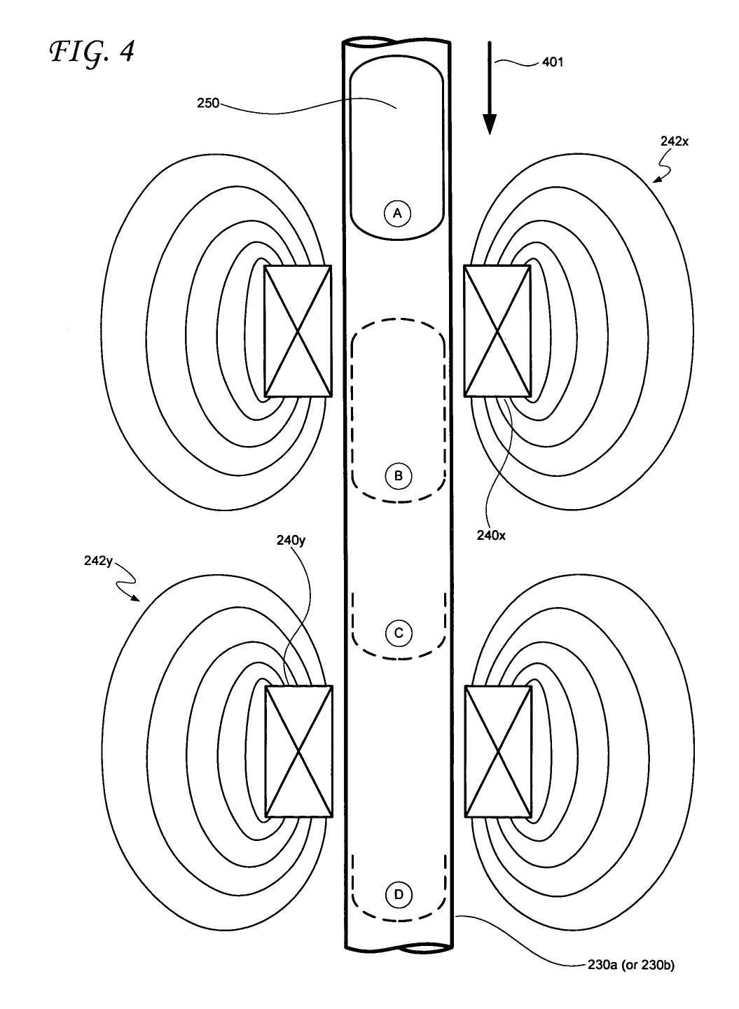

With reference now to FIG. 4, in conjunction with FIG. 2, operation of the fluid cooling system 200 will be explained in greater detail. FIG. 4 illustrates two of the electromagnetic elements disposed on the flow path 235 (e.g., on either of the first or second fluid conduits 230a, 230b), these two flow elements being denoted as 240x and 240y. This figure also shows a representation of a magnetic field that may be generated by each of these electromagnetic elements 240x, 240y, which are identified as 242x and 242y, respectively (note that, although both magnetic fields 242x, 242y are shown in FIG. 4, in some embodiments only one of the electromagnetic elements 240x, 240y may be activated at any given time, as will be explained below). One of the flow elements 250 is also shown in FIG. 4, with a first position of this flow element being shown in solid line (denoted by reference numeral A). Subsequent positions of the flow element 250 are shown in dashed line (and are denoted by reference numerals B, C, and D, respectively). The direction of movement of flow element 250 is shown by an arrow 401.

When the flow element 250 moves into a position where the element is within the magnetic field 242x generated by electromagnetic element 240x, this magnetic field will exert a force on the flow element that will tend to “pull” the flow element toward the electromagnetic element 240x. This “pulling” force will cause the flow element 250 to continue moving in the direction of arrow 401. As the reader will appreciate, the strength of the magnetic field 242x will decrease with increasing distance away from the electromagnetic element 242x. Thus, the force exerted by the magnetic field 242x on the flow element 250 may increase as the flow element gets closer to the electromagnetic element 240.

As the flow element 250 continues moving through the flow path, it will move away from the electromagnetic element 240x (see position B), and the force exerted on the flow element by this electromagnetic element will decline. The flow element 250 will then approach the magnetic field 242y generated by the next electromagnetic element 240y (see position C), and this electromagnetic element will then exert a “pulling” force on the flow element. The force applied to the flow element 250 by electromagnetic element 242y will propel the flow element, causing the flow element to move further down the flow path in the direction denoted by the arrow 401 (see position D). A pressure head will be created in the fluid within the flow path as the flow element 250 moves between the electromagnetic elements—e.g., from position A to position D between electromagnetic elements 240x, 240y—and this pressure head will cause the fluid to flow through the flow path (also in the direction of arrow 401).

In one embodiment, the controller 260 activates the electromagnetic elements 240 in a desired sequence to move the flow element or elements 250. According to one embodiment, the controller 240 can switch each of the electromagnetic elements between an “ON” state and an “OFF” state. In the ON state, a current may be supplied to an electromagnetic element, which causes the electromagnetic element to generate a magnetic field having a strength sufficient to propel a flow element (e.g., sufficient to exert a “pulling” force on the flow element). In the OFF state, no current is supplied to the electromagnetic device (or an insufficient current is supplied, which does not result in the generation of a magnetic field of a strength sufficient to propel a flow element).

In one embodiment, for each flow element 250, only one electromagnetic element is actuated at a time to propel the flow element. Thus, returning to the example of FIG. 4, the first electromagnetic element 240x is switched to the ON state to propel the flow element 250 (while the electromagnetic element 240y, as well as other electromagnetic elements in the vicinity of this flow element, are maintained in the OFF state). As the flow element travels past the electromagnetic element 240x and approaches the next electromagnetic element 240y, the first electromagnetic element 240x is switched to the OFF state and the second electromagnetic element 240y is switched to the ON state. The second electromagnetic element 240y then continues to propel the flow element 250. In other words, one could view the first electromagnetic element 240x as “handing off” the flow element 250 to the second electromagnetic element 240y, which in turn will “hand off” the flow element to the next electromagnetic element along the flow path.

According to other embodiments, however, more than one electromagnetic element 240 may be activated at any given time for each flow element 250. For example, returning again to FIG. 4, the first electromagnetic element 240x may be maintained in the ON state while the next electromagnetic element 240y is switched ON. After the second electromagnetic element 240y is activated, the first electromagnetic element 240x may be maintained in the ON state for a short period of time and then switched to the OFF state. However, depending upon the spacing between electromagnetic elements, having two adjacent elements activated simultaneously may result in their magnetic fields “competing” with one another as each acts on a flow element 250 disposed between them.

In one embodiment, the spacing between adjacent electromagnetic elements is such that their magnetic fields overlap. For example, with reference again to FIG. 4, the spacing between the flow elements 240x, 240y may be such that when the second electromagnetic element 240y is switched to the ON state (and, perhaps, the first electromagnetic element 240x switched to the OFF state), the magnetic field 242y generated by the second electromagnetic element begins to exert a “pulling” force on the flow element 250. Thus, in some embodiments, a magnetic field may always be acting upon a flow element.

According to another embodiment, in addition to being propelled by the forces exerted upon them by the electromagnetic elements, the flow element (or elements) may also move under their own momentum (as well as under the momentum of the moving fluid). For example, two adjacent electromagnetic elements may be spaced apart a distance such that their magnetic fields do not overlap (or are of insufficient strength at their outer peripheries), such that there is a “field gap” between them. Within this field gap, no electromagnetic field (or a field of insufficient strength) is exerted on a flow element positioned within the gap. However, the momentum of a flow element within such a field gap (as well as the momentum of the moving fluid) may continue to move the flow element until a magnetic force is again exerted on the flow element. Also, in another embodiment, a switching delay may exist between two adjacent electromagnetic elements. For example, returning to FIG. 4, when the first electromagnetic element 240x is switched from ON to the OFF state, there may be a short delay before the next electromagnetic element 240y is switch from OFF to the ON state. During this switching delay, in which no magnetic field may be acting on the flow element 250, the flow element may continue to move due to its own momentum (and that of the moving fluid).

As previously noted, any suitable number of flow elements 250 may be used, and according to some embodiments two or more flow elements may be employed. Where two or more flow elements 250 are used, it should be understood that multiple electromagnetic elements 240 may be powered ON at any given time, with one electromagnetic element (or perhaps two) ON at any instant in time for each flow element in the flow path. Where multiple flow elements 250 are used, one concern is that over time the spacing between flow elements may be compromised, such that the flow elements become “bunched” together. However, according to one embodiment, the controller 260 actuates the electromagnetic elements 240 in a desired sequence that maintains the spacing between flow elements 250. Again, the flow elements 250 may be maintained in an equidistantly spaced apart relationship (or approximately equidistant), or they may be spaced apart in some other fashion.

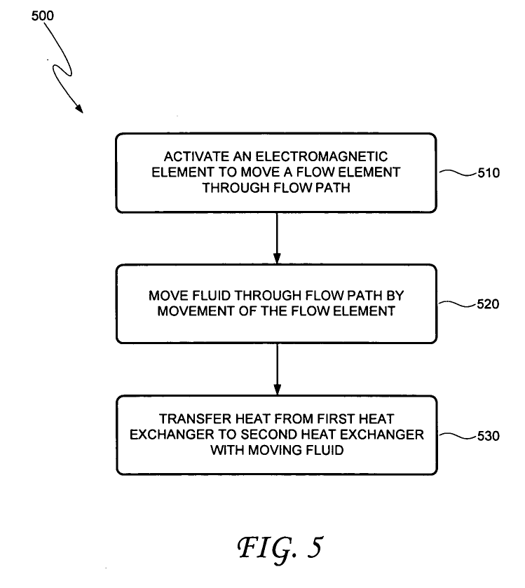

Turning now to FIG. 5, illustrated is an embodiment of a method 500 for cooling an IC die (or other device), as may be performed by the cooling system 200 shown in FIG. 2 through 4. Referring to block 510, an electromagnetic element 240 is activated to move a flow element 250 through the flow path 235. Movement of one or more flow elements 250 by actuation of the electromagnetic elements 240 was previously described. Again, movement of the flow element (or elements) 250 will create a pressure head within the fluid in the flow path 235 and, as set forth in block 520, this pressure head created by the moving flow element(s) causes movement of the fluid through the flow path. As set forth in block 530, the moving fluid can transfer heat from the first heat exchanger 210 to the second heat exchanger 220. Again, as previously described, the heat received from heat source 205 can heat the fluid flowing through the first heat exchanger 210, and this fluid is circulated to the second heat exchanger 220, which may exhaust the heat to the surrounding environment.

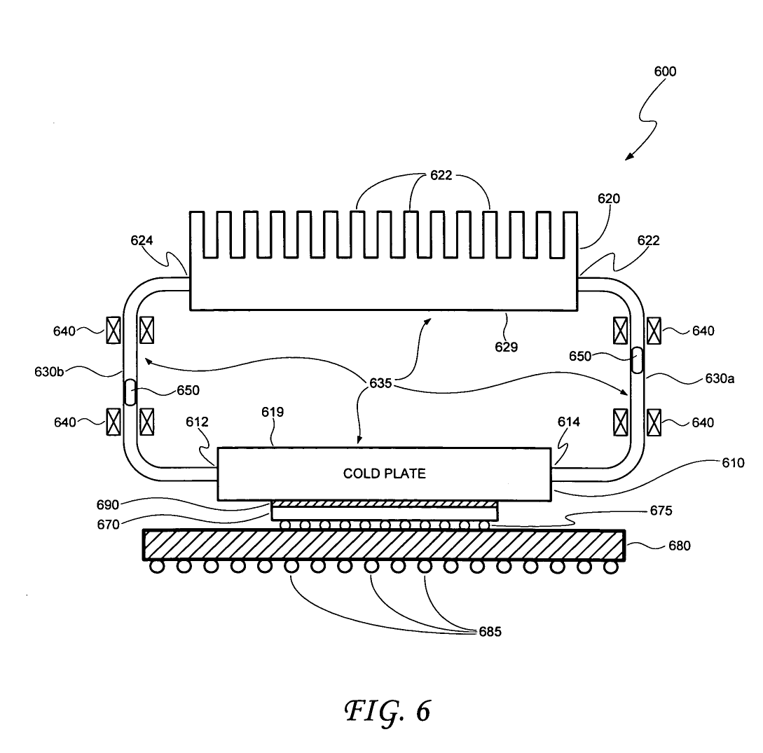

Illustrated in FIG. 6 is an embodiment of an IC device 600. The IC device 600 may employ a cooling system similar to that described above in FIGS. 2 through 4, as well as the cooling method 500 of FIG. 5.

Referring to FIG. 6, the IC device 600 includes a die 670 that is disposed on a substrate 680 (e.g., a package substrate). The die 670 may comprise a microprocessor, a network processor, an ASIC, an FPGA, or other processing device. A plurality of bond pads (or other leads) on the die 670 may be electrically connected to a corresponding plurality of lands (or other leads) on the substrate 680 by an array of solder bumps 675 (or columns, or other interconnects). Circuitry on the package substrate 680 can route signal lines from the die leads to locations on the substrate 680 where electrical connections can be established with a next-level component (e.g., a motherboard, a computer system, a circuit board, another IC device, etc.). For example, the substrate circuitry may route signal lines to a ball-grid array 685 (or a pin-grid array) formed on a lower surface of the package substrate. The ball-grid (or pin-grid) array then electrically couples the die to the next-level component, which includes a mating array of terminals (e.g., bond pads, pin sockets, etc.).

The IC device 600 also includes a cooling system which comprises a cold plate 610, a heat exchanger 620, a first fluid conduit 630a, a second fluid conduct 630b, a number of electromagnetic elements 640, at least one flow element 650, and a controller (not shown in FIG. 6). The cold plate 610 is thermally coupled with the die 670, such that heat generated by the die during operation can be transferred to the cold plate. According to one embodiment, a thermal interface 690 couples—both mechanically and thermally—the die 670 to the cold plate 610. The thermal interface 690 may, in one embodiment, comprise a layer of a solder, or any other material layer or device that can conduct heat from the die 670 to the cold plate 610, as well as mechanically attach the cold plate to the die.

The cold plate 610 comprises a plate formed from a metal (e.g., copper) or other thermally conductive material. A channel (or channels) extends through the cold plate 610, and a fluid can flow through this channel. As noted above, heat generated by the die 670 is transferred to the cold plate 610. Heat is also transferred to the fluid flowing through the channel in the cold plate, which heats the moving fluid and transports this energy away from the cold plate (and die). The heated fluid is than circulated to the heat exchanger 620, which can transfer heat to the ambient environment. The cold plate 610 includes an inlet 612 and an outlet 614, both of which are in fluid communication with the channel (or channels) extending through the cold plate. Outlet 614 is coupled with the first fluid conduit 630a, and inlet 612 is coupled with the second fluid conduit 630b.

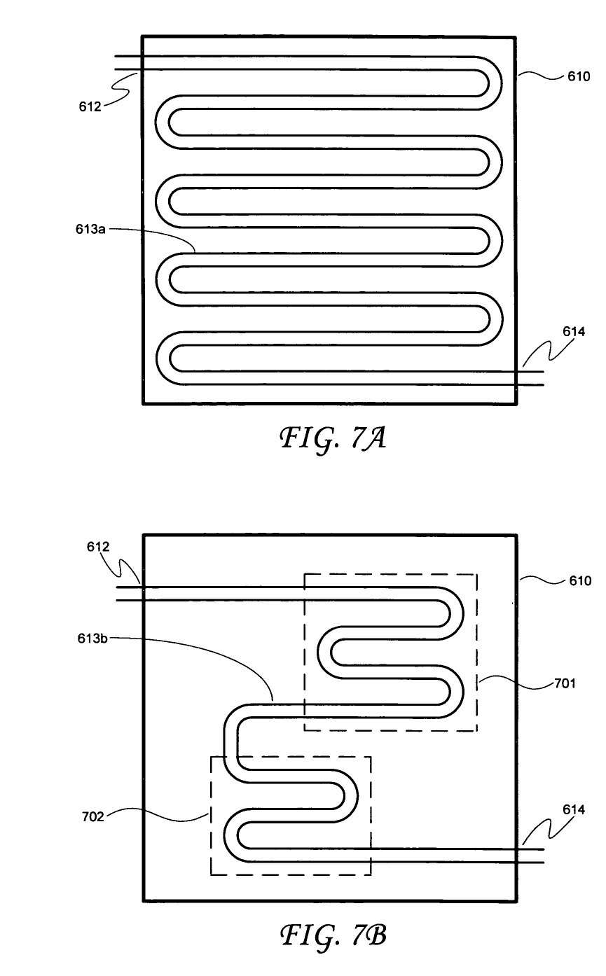

Various embodiments of the cold plate 610 are illustrated in FIGS. 7A and 7B. Referring first to FIG. 7A, one embodiment of a channel 613a extending through the cold plate 610 is shown. The channel 613a comprises a serpentine fluid path that extends between the inlet 612 and the outlet 614. Turning to FIG. 7B, another embodiment of a channel 613b extending through the cold plate is illustrated. Channel 613b also comprises a serpentine fluid path extending between the inlet 612 and outlet 614. However, the channel 613b directs fluid over specific regions 701, 702 of the underlying die 670, which regions of the die may include “hot spots.” It should be understood that FIGS. 7A and 7B represent just few embodiments of the cold plate 610 and, further, that the cold plate 610 may include any suitable number and configuration of channels or other fluid paths.

The heat exchanger 620 includes an inlet 622 and an outlet 624. The inlet 622 is coupled with the first fluid conduit 630a, which is also coupled with the outlet 614 of cold plate 610, as noted above. The outlet 624 is coupled with the second fluid conduit 630b, the second fluid conduit being coupled with the inlet 612 of the cold plate, as also noted above. The heat exchanger 620 comprises any device that can receive a heated fluid from the cold plate 610 and cool this fluid. In one embodiment, as illustrated in FIG. 6, the heat exchanger 620 comprises a device that cools the heated fluid by dissipating heat to the surrounding environment (e.g., ambient air). In the illustrated embodiment, the heat exchanger 620 comprises a finned heat sink constructed from a metal (e.g., copper), or other thermally conductive material. The heat exchanger 620 includes a channel (or channels) to receive the heated fluid, and in one embodiment this channel comprises a serpentine fluid path (e.g., similar to the channel 613a shown in FIG. 7A). Heated fluid is directed into the channel of the heat exchanger (at inlet 622), and heat from the fluid is transferred to the metal heat sink. Heat is then conducted through the heat sink to a number of fins 622 (or other surface features providing increased surface area), and heat is transferred from these fins to the surrounding environment (e.g., as by convection).

According to one embodiment, the heat exchanger 620 is spaced apart from the cold plate 610, as illustrated in FIG. 6. For example, the heat exchanger 620 may be mounted on another component (e.g., a circuit board, a mother board, etc.). In alternative embodiment, the heat exchanger 620 may be mounted onto the cold plate 610 (e.g., the underside 629 of heat exchanger 620 may be mechanically and thermally coupled with the upper surface 619 of cold plate 610). In yet a further embodiment, a fan (not shown in figures) or other active cooling device may be mounted proximate the heat exchanger 620, such a fan capable of creating a flow of air over the heat exchanger 620.

Each of the first and second fluid conduits 630a, 630b may comprise any device through which a fluid may flow and, further, through which a flow element 650 can move. According to one embodiment, each of the first and second fluid conduits 630a, 630b comprises a section of tubing. The tubing may comprise a flexible material, such as a plastic material, or a more rigid material, such as a metal. This tubing may be coupled with the cold plate 610 and heat exchanger 620 using any suitable device or technique (e.g., as by a threaded connection, by swaging, by epoxy bonding, by brazing or welding, etc.).

The first fluid conduit 630a, the second fluid conduit 630b, the channel (or channels) in cold plate 610, and the channel (or channels) in heat exchanger 620 provide a flow path 635. In one embodiment, this flow path 635 comprises a closed-loop flow path. The flow path 635 provides for the circulation of a fluid between the cold plate 610 and the heat exchanger 620, and the fluid may be circulated through the flow path by electromagnetically pumping the fluid, as previously described. It should be understood that, although referred to as a closed-loop flow path in some embodiments, such a closed-loop flow path may suffer from a small amount of leakage. Also, in other embodiments, the flow path 635 may not be a closed-loop system.

The fluid circulating in flow path 635 may comprise any fluid capable of receiving heat from the cold plate 610 and transporting heat to the heat exchanger 620. In one embodiment, the fluid comprises a liquid. For example, the fluid may comprise water, a mixture of water and a corrosion inhibitor, a mixture of water and ethylene glycol, a mixture of water and propylene glycol, an alcohol (e.g., ethanol), or a light weight oil. Also, either single-phase cooling (e.g., where the fluid remains a liquid) or two-phase cooling (e.g., where a portion of a liquid coolant is vaporized to create a liquid-vapor mixture) may be employed.

The IC device 600 includes a number of electromagnetic elements 640, one or more flow elements 650, and a controller (not shown in FIG. 6), as noted above. The electromagnetic elements 640 can move the flow element or elements 650 through the flow path 635, and the moving flow elements can create a pressure head within the flow path, which may cause the fluid within the flow path to circulate. Thus, the electromagnetic elements 640 and flow elements 650, in conjunction with the controller, may form a system for pumping fluid through the flow path 635, which includes cold plate 610 and heat exchanger 620.

As suggested above, each of the electromagnetic elements 640 may be in communication (e.g., electrical communication) with the controller, and the controller will control switching of the electromagnetic elements—e.g., between either an “ON” state and an “OFF” state—in a desired sequence, as described above with respect to FIGS. 2 through 4. In one embodiment, each of the electromagnetic elements 640 may be in communication with the controller. The controller may comprise any suitable circuitry or device capable of controlling operation of the electromagnetic elements 640. In one embodiment, the controller comprises circuitry formed on the IC die 670. According to another embodiment, the controller comprises a device or circuitry external to the die.

Each of the electromagnetic elements 640 may comprise any device which is capable of generating a magnetic field sufficient to move a flow element 650 through the flow path 635. In one embodiment, an electromagnetic element 640 comprises a toroidal shaped electromagnet that extends around a portion of the flow path 635 (e.g., around either of the first and second fluid conduits 630a, 630b, or around a channel in either of the cold plate 610 and the heat exchanger 620). According to one embodiment, a toroidal shaped electromagnet may comprise a coil of wire (e.g., copper wire). Such a toroidal shaped electromagnet can generate a magnetic field that may exert a “pulling” force on a flow element 650 (and, perhaps, a “pushing” force, where the flow element itself comprises a permanent magnet or is otherwise capable of generating its own magnetic field).

A flow element 650 may comprise any device which can be caused to move under application of a magnetic field (e.g., a magnetic field generated by one of the electromagnetic elements 640). As previously noted, movement of the flow element (or elements) 650 creates a pressure head within the fluid contained in the flow path 635, and this pressure head will pump the fluid through the flow path. The flow element (or elements) 650 may comprise a device similar to any of the flow elements described in FIGS. 3A through 3C and the accompanying text above. Any suitable number of flow elements 650 may be disposed in the flow path 635. In one embodiment, one flow element 650 is used, and in other embodiments two or more flow elements 650 are employed. According to one embodiment, where two or more flow elements 650 are used, these elements are maintained in an equidistantly (or approximately equidistant) spaced-apart relationship within the flow path 635. In other embodiments, however, the flow elements 650 may be spaced-apart in some other fashion.

The fluid cooling system of IC device 600—e.g., cold plate 610, heat exchanger 620, fluid conduits 630a-b, electromagnetic elements 640, flow elements 650, and the controller—may operate in accordance with any of the above-described embodiments. In one embodiment, the cooling system of IC device 600 may operate in a manner similar to the cooling system 200, as described in FIGS. 2 through 4, and the accompanying text above. In another embodiment, the cooling system of IC device 600 operates in a manner similar to the method of cooling 500, as described in FIG. 5 and the accompanying text above.

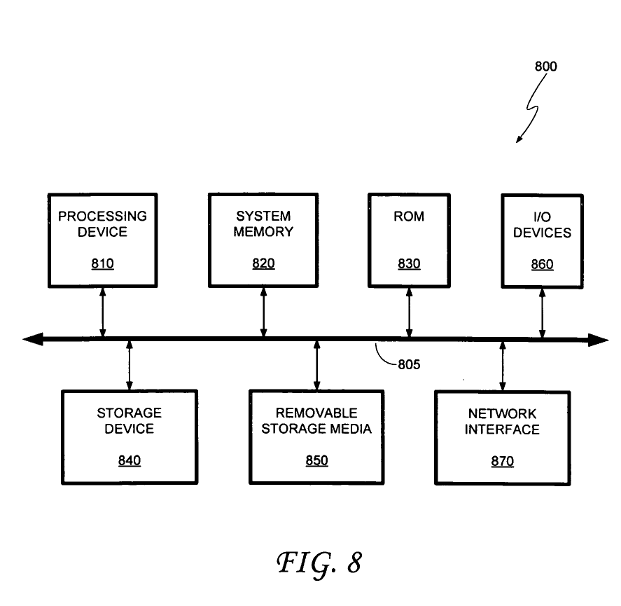

Referring to FIG. 8, illustrated is an embodiment of a computer system 800. Computer system 800 includes a bus 805 to which various components are coupled. Bus 805 is intended to represent a collection of one or more buses—e.g., a system bus, a Peripheral Component Interface (PCI) bus, a Small Computer System Interface (SCSI) bus, etc.—that interconnect the components of system 800. Representation of these buses as a single bus 805 is provided for ease of understanding, and it should be understood that the system 800 is not so limited. Those of ordinary skill in the art will appreciate that the computer system 800 may have any suitable bus architecture and may include any number and combination of buses.

Coupled with bus 805 is a processing device (or devices) 810. The processing device 810 may comprise any suitable processing device or system, including a microprocessor, a network processor, an ASIC, an FPGA, or similar device. It should be understood that, although FIG. 8 shows a single processing device 810, the computer system 800 may include two or more processing devices.

Computer system 800 also includes system memory 820 coupled with bus 805, the system memory 810 comprising, for example, any suitable type and number of memories, such as static random access memory (SRAM), dynamic random access memory (DRAM), synchronous DRAM (SDRAM), or double data rate DRAM (DDRDRAM). During operation of computer system 800, an operating system and other applications may be resident in the system memory 820.

The computer system 800 may further include a read-only memory (ROM) 830 coupled with the bus 805. During operation, the ROM 830 may store temporary instructions and variables for processing device 810. The system 800 may also include a storage device (or devices) 840 coupled with the bus 805. The storage device 840 comprises any suitable non-volatile memory, such as, for example, a hard disk drive. The operating system and other programs may be stored in the storage device 840. Further, a device 850 for accessing removable storage media (e.g., a floppy disk drive or a CD ROM drive) may be coupled with bus 805.

The computer system 800 may also include one or more I/O (Input/Output) devices 860 coupled with the bus 805. Common input devices include keyboards, pointing devices such as a mouse, as well as other data entry devices, whereas common output devices include video displays, printing devices, and audio output devices. It will be appreciated that these are but a few examples of the types of I/O devices that may be coupled with the computer system 800.

The computer system 800 further comprises a network interface 870 coupled with bus 805. The network interface 870 comprises any suitable hardware, software, or combination of hardware and software that is capable of coupling the system 800 with a network (e.g., a network interface card). The network interface 870 may establish a link with the network (or networks) over any suitable medium—e.g., wireless, copper wire, fiber optic, or a combination thereof—supporting the exchange of information via any suitable protocol—e.g., TCP/IP (Transmission Control Protocol/Internet Protocol), HTTP (Hyper-Text Transmission Protocol), as well as others.

It should be understood that the computer system 800 illustrated in FIG. 8 is intended to represent an exemplary embodiment of such a system and, further, that this system may include many additional components, which have been omitted for clarity and ease of understanding. By way of example, the system 800 may include a DMA (direct memory access) controller, a chip set associated with the processing device 810, additional memory (e.g., a cache memory), as well as additional signal lines and buses. Also, it should be understood that the computer system 800 may not include all of the components shown in FIG. 8.

In one embodiment, the computer system 800 includes a component having a liquid cooling system that moves a fluid by electromagnetically pumping the fluid, as described above with respect to FIGS. 2 through 7. For example, the processing device 810 of system 800 may include the cooling system 200 of FIG. 2, and/or the processing device 810 may be embodied as the IC device 600 of FIG. 6. However, it should be understood that other components of system 800 (e.g., network interface 870, etc.) may include any of the disclosed embodiments of a liquid cooling system.

The foregoing detailed description and accompanying drawings are only illustrative and not restrictive. They have been provided primarily for a clear and comprehensive understanding of the disclosed embodiments and no unnecessary limitations are to be understood therefrom. Numerous additions, deletions, and modifications to the embodiments described herein, as well as alternative arrangements, may be devised by those skilled in the art without departing from the spirit of the disclosed embodiments and the scope of the appended claims.

What is claimed is:

1. An apparatus comprising:
a ferrous element disposed within a fluid path; and
a number of electromagnetic elements, wherein actuation of at least one of the electromagnetic elements moves the ferrous element within the fluid path and movement of the ferrous element moves a fluid through the fluid path.

2. The apparatus of claim 1, further comprising:
a first heat exchanger in fluid communication with the fluid path; and
a second heat exchanger in fluid communication with the fluid path;
wherein the moving fluid transfers heat from the first heat exchanger to the second heat exchanger.

3. The apparatus of claim 1, wherein each of the electromagnetic elements comprises a toroidal-shaped electromagnet.

4. The apparatus of claim 1, wherein the ferrous element comprises:
a flexible outer shell; and
a ferrous substance disposed within the flexible outer shell.

5. A system comprising:
a fluid path;
a flow element disposed within the fluid path;
a number of electromagnetic elements, wherein activation of at least one of the electromagnetic elements moves the flow element within the fluid path; and
a fluid disposed within the fluid path, wherein movement of the flow element moves the fluid through the fluid path.

6. The system of claim 5, wherein the fluid path comprises a closed loop fluid path.

7. The system of claim 5, wherein the flow element comprises:
an outer shell; and
a ferrous substance disposed within the outer shell.

8. The system of claim 7, wherein the outer shell comprises a flexible material.

9. The system of claim 7, wherein the ferrous substance comprises a plurality of metallic particles suspended in a liquid.

10. The system of claim 7, wherein the ferrous substance comprises a plurality of metallic particles.

11. The system of claim 5, further comprising:
a first heat exchanger in fluid communication with the fluid path, the first heat exchanger to receive heat from a heat source; and
a second heat exchanger in fluid communication with the fluid path;
wherein the moving fluid transfers heat from the first heat exchanger to the second heat exchanger, the second heat exchanger to transfer heat to the surrounding environment.

12. The system of claim 11, wherein the heat source comprises an integrated circuit die.

13. The system of claim 5, further comprising at least one other flow element.

14. The system of claim 5, further comprising a controller in communication with the electromagnetic elements, the controller to control activation of the electromagnetic elements.

15. A device comprising:
an integrated circuit die;
a cold plate coupled with the die, the cold plate to receive heat from the die, the cold plate having an inlet and an outlet;
a heat exchanger having an inlet and an outlet;
a first fluid conduit extending from the cold plate outlet to the heat exchanger inlet;
a second fluid conduit extending from the heat exchanger outlet to the cold plate inlet, wherein the first and second fluid conduits, the cold plate, and the heat exchanger provide a fluid path;
a flow element disposed within the fluid path; and
a number of electromagnetic elements to move the flow element through the fluid path, movement of the flow element to move a fluid through the fluid path, the moving fluid to transfer heat from the cold plate to the heat exchanger.

16. The device of claim 15, wherein the heat exchanger transfer heat to a surrounding environment.

17. The device of claim 15, further comprising at least one other flow element.

18. The device of claim 17, wherein the flow element and the at least one other flow element are maintained in an approximately equidistant spaced-apart relationship.

19. The device of claim 15, wherein the die comprises a processing device.

20. The device of claim 15, further comprising a controller in communication with the electromagnetic elements, the controller to control activation of the electromagnetic elements.

21. The device of claim 20, wherein the controller comprises circuitry disposed on the die.

22. A method comprising:
activating a first of a number of electromagnetic elements to move a flow element through a fluid path, wherein the movement of the flow element moves a fluid through the fluid path; and
transferring heat from a first heat exchanger to a second heat exchanger with the moving fluid.

23. The method of claim 22, further comprising activating a second of the electromagnetic elements to move the flow element.

24. The method of claim 23, further comprising switching the first electromagnetic element off prior to activating the second electromagnetic element.

25. The method of claim 22, further comprising sequentially activating the number of electromagnetic elements to move the flow element through the fluid path.

26. The method of claim 25, wherein one of the electromagnetic elements is activated at a time.

27. The method of claim 22, further comprising activating a second of the electromagnetic elements to move another flow element within the fluid path.

28. The method of claim 27, wherein the first and second electromagnetic elements are both activated at the same time.

29. The method of claim 22, further comprising:
transferring heat from an integrated circuit die to the first heat exchanger; and
transferring heat from the second heat exchanger to a surrounding environment.

30. The method of claim 22, further comprising:
moving a number of flow elements through the fluid path using the electromagnetic elements;
wherein the number of flow elements are maintained in an approximately equidistant spaced-apart relationship.
